(19) United States
(12) Patent Application Publication
(10) Pub. No.: US 2024/0290551 A1
(43) Pub. Date: Aug. 29, 2024

(54) TRANSPARENT ELECTRODE FOR SOLAR CELL AND METHOD OF MANUFACTURING SAME

(71) Applicants: Hyundai Motor Company, Seoul (KR); Kia Corporation, Seoul (KR); Industry-Academic Cooperation Foundation, Yonsei University, Seoul (KR)

(72) Inventors: Yeong Hee Lee, Yongin (KR); Ri Ra Kang, Uiwang (KR); Kyoung Han Ryu, Yongin (KR); Byung Hong Lee, Suwon (KR); Sang Il Lee, Seoul (KR); In Sik Yun, Changwon (KR); Jang Ung Park, Seoul (KR)

(21) Appl. No.: 18/636,952

(22) Filed: Apr. 16, 2024

Related U.S. Application Data
(62) Division of application No. 17/940,309, filed on Sep. 8, 2022.

(30) Foreign Application Priority Data
Sep. 9, 2021 (KR) 10-2021-0120150

(51) Int. Cl. H01G 9/20; H01G 9/00; H01G 9/042

(52) U.S. Cl. CPC H01G 9/20; H01G 9/0029; H01G 9/042; H01G 9/2027

(57) ABSTRACT

Disclosed are a transparent electrode for a solar cell and a method of manufacturing the same. The transparent electrode for a solar cell has a low Young's modulus, excellent elasticity, self-healing properties, an average visible-light transmittance sufficient to implement bifacial properties, and excellent power conversion efficiency (PCE). In addition, the method of manufacturing the transparent electrode for a solar cell does not require an additional deposition process, so the electrode-manufacturing time can be reduced, and the electrode-manufacturing process can be performed separately from other solar-cell-manufacturing processes, which is advantageous for mass production and large-area application.

### CROSS-REFERENCE TO RELATED APPLICATION

This application is based on and claims under 35 U.S.C. § 119(a) the benefit of Korean Patent Application No. 10-2021-0120150, filed on Sep. 9, 2021, the entire contents of which are incorporated herein by reference.

### TECHNICAL FIELD

Embodiments of the present disclosure relate to a transparent electrode for a solar cell and a method of manufacturing the same.

### BACKGROUND ART

The top electrode of a conventional solar cell is typically an opaque top electrode. However, the top electrode must additionally exhibit transparency in order to allow light to pass therethrough to reach a hybrid battery, etc., so a method of replacing the top electrode with a transparent electrode has been under study recently.

In the case in which a transparent electrode is sputtered, a buffer layer may be introduced and deposited, but Transmittance for the light conversion efficiency is low, and stability is poor compared to the conventional opaque top electrode.

Most transparent electrodes that have been exhibited the high sheet resistance, poor transmittance and other undesirable negative effects on additional processes, so the energy conversion efficiency of the solar cell is decreased compared to the opaque one.

### SUMMARY

In one aspect, a transparent electrode for a solar cell is provided, which includes a main conductive part having a plurality of grid structures made of liquid metal and formed at a specific pitch and width, a protective part surrounding the same, and an auxiliary conductive part located under the main conductive part, and a method of manufacturing the same.

An exemplary embodiment of the present invention provides a transparent electrode for a solar cell, comprising a main conductive part having a plurality of grid structures including line patterns which are formed of liquid metal, a protective part surrounding the plurality of grid structures and including an elastomer, and an auxiliary conductive part located under the grid structures of the main conductive part and including a conductive material.

As referred to herein, a liquid metal is a metal or metal alloy or other metal composition that is a liquid or fluid at room temperature (25° C. or 30° C.). In some aspects, the liquid metal is an alloy or other composition of two or more metals. In some aspects, the liquid metal s a eutectic composition of two or more metals. In some aspects, the liquid metal may comprise one or more of any of gallium, indium, or tin.

In some embodiments, the liquid metal may be a eutectic gallium-indium alloy (EGaIn).

In some embodiments, the liquid metal comprises GaInSn (Galinstan).

In some embodiments, the width of the line patterns may be 1 to 20 μm.

In some embodiments, the pitch of the grid structures may be 100 to 500 μm.

In some embodiments, the elastomer may include at least one selected from the group consisting of polydimethylsiloxane (PDMS) and thermoplastic polyurethane elastomer (TPE).

In some embodiments, the elastomer is PDMS, which is transparent in the range of visible and infrared.

In some embodiments, the conductive material may include at least one selected from the group consisting of indium tin oxide (ITO), transparent conductive oxide (TCO), carbon nanomaterial, and conductive polymer.

In some embodiments, the conductive material is ITO, which is transparent in the range of visible and infrared.

In some embodiments, the transparent electrode may be used as a top electrode of a perovskite solar cell.

In some embodiments, the transparent electrode may have power conversion efficiency (PCE) of 10% to 14%.

In some embodiments, the transparent electrode may have average visible-light transmittance (AVT) of 78% to 82%.

In a further aspect, a metho of manufacturing a transparent electrode for a solar cell is provided, the method comprising: (a) applying a sacrificial layer on a substrate; (b) forming a plurality of grid structures on the sacrificial layer using a liquid metal to provide a main conductive part; (c) forming a protective part so as to contact or surround the plurality of grid structures; and (d) separating the substrate from the main conductive part and the protective part.

In preferred aspects, the method may further comprise (e) locating an auxiliary conductive part comprising a conductive material so as to be provided with the grid structures of the main conductive part.

In a preferred aspect, a plurality of grid structures may be formed on the sacrificial layer by use of a printing process, i.e. a lithographic process which may include use of a photoresist and imaging mask.

In a preferred aspect, a protective part is formed to contact or surround the plurality of grid structures by one or more steps that may include placing an elastomer on the main conductive part.

In a preferred aspect, separating the substrate from the main conductive part and the protective part may comprise removing the sacrificial layer.

In a preferred embodiment, a method of manufacturing a transparent electrode for a solar cell is providing, which suitably comprises applying a sacrificial layer on a substrate, forming a main conductive part by forming a plurality of grid structures on the sacrificial layer through a printing process using a liquid metal, forming a protective part so as to surround the plurality of grid structures by placing an elastomer on the main conductive part, separating the substrate from the main conductive part and the protective part by removing the sacrificial layer, and locating an auxiliary conductive part comprising a conductive material so as to be provided under the grid structures of the main conductive part.

In some embodiments, the sacrificial layer may include at least one selected from the group consisting of LOR (lift-off resist) 3A and PMMA (poly(methyl methacrylate)). In another embodiment, vehicles and solar cells are provided that comprise the transparent electrode as disclosed herein.

In one aspect, a perovskite solar cell is provided that comprises an electrode as disclosed herein, including where the electrode is a top electrode of the perovskite solar cell.

### BRIEF DESCRIPTION OF THE DRAWINGS

The above and other features of the present invention will now be described in detail with reference to certain exemplary embodiments thereof, illustrated in the accompanying drawings which are given hereinbelow by way of illustration only, and thus are not limitative of the present invention, and wherein:

FIG. 1 is a cross-sectional view of a transparent electrode for a solar cell according to an exemplary embodiment;

FIG. 2 is an enlarged plan view of the grid structure of the main conductive part in the transparent electrode for a solar cell according to an exemplary embodiment; and

FIG. 3 is a graph showing the transmittance (%) of the top electrode (ITO) of Comparative Example 1 and the top electrode of Example 1 depending on the wavelength (nm).

### DETAILED DESCRIPTION

The above and other objects, features and advantages of the present invention will be more clearly understood from the following preferred embodiments taken in conjunction with the accompanying drawings. However, the present invention is not limited to the embodiments disclosed herein, and may be modified into different forms. These embodiments are provided to thoroughly explain the present disclosure and to sufficiently transfer the spirit of the present invention to those skilled in the art.

Throughout the drawings, the same reference numerals will refer to the same or like elements. For the sake of clarity of the present invention, the dimensions of structures are depicted as being larger than the actual sizes thereof. It will be understood that, although terms such as “first”, “second”, etc. may be used herein to describe various elements, these elements are not to be limited by these terms. These terms are only used to distinguish one element from another element. For instance, a “first” element discussed below could be termed a “second” element without departing from the scope of the present invention. Similarly, the “second” element could also be termed a “first” element. As used herein, the singular forms are intended to include the plural forms as well, unless the context clearly indicates otherwise.

It will be further understood that the terms “comprise”, “include”, “have”, etc., when used in this specification, specify the presence of stated features, integers, steps, operations, elements, components, or combinations thereof, but do not preclude the presence or addition of one or more other features, integers, steps, operations, elements, components, or combinations thereof. Also, it will be understood that when an element such as a layer, film, area, or sheet is referred to as being “on” another element, it may be directly on the other element, or intervening elements may be present therebetween. Similarly, when an element such as a layer, film, area, or sheet is referred to as being “under” another element, it may be directly under the other element, or intervening elements may be present therebetween.

Unless otherwise specified, all numbers, values, and/or representations that express the amounts of components, reaction conditions, polymer compositions, and mixtures used herein are to be taken as approximations including various uncertainties affecting measurement that inherently occur in obtaining these values, among others, and thus should be understood to be modified by the term “about” in all cases. Furthermore, when a numerical range is disclosed in this specification, the range is continuous, and includes all values from the minimum value of said range to the maximum value thereof, unless otherwise indicated. Moreover, when such a range pertains to integer values, all integers including the minimum value to the maximum value are included, unless otherwise indicated.

In the present disclosure, when a range is described for a variable, it will be understood that the variable includes all values within the stated range, including the end points. For example, the range of “5 to 10” will be understood to include any subranges, such as 6 to 10, 7 to 10, 6 to 9, 7 to 9 and the like, as well as individual values of 5, 6, 7, 8, 9 and 10, and will also be understood to include any value between valid integers within the stated range, such as 5.5, 6.5, 7.5, 5.5 to 8.5, 6.5 to 9, and the like. Also, for example, the range of “10% to 30%” will be understood to include subranges, such as 10% to 15%, 12% to 18%, 20% to 30%, etc., as well as all integers including values of 10%, 11%, 12%, 13% and the like up to 30%, and will also be understood to include any value between valid integers within the stated range, such as 10.5%, 15.5%, 25.5%, and the like.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

The top electrode of a conventional solar cell is typically an opaque top electrode. However, the top electrode must additionally exhibit transparency in order to allow light to pass therethrough to reach a hybrid battery, etc., so a method of replacing the top electrode with a transparent electrode has been under development recently. Most transparent electrodes that have been exhibited the high sheet resistance, poor transmittance and other undesirable negative effects on additional processes, so the energy conversion efficiency of the solar cell is decreased compared to the opaque one.

The transparent electrode for the solar cell according to the present invention is to solve the above problem. The transparent electrode has a short manufacturing time and does not require an additional deposition process. In addition, the transparent electrode has excellent power conversion efficiency even when used as an upper electrode, and has excellent average visible light transmittance due to bifacial properties.

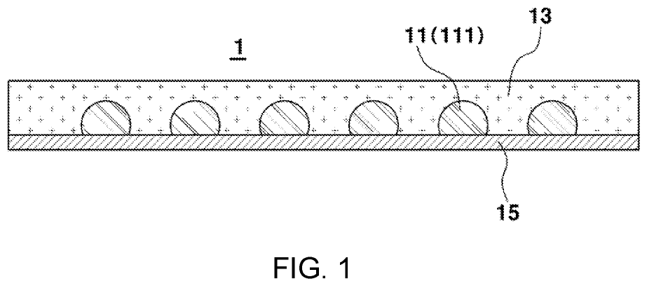

FIG. 1 is a cross-sectional view of a transparent electrode 1 for a solar cell according to an exemplary embodiment. With reference thereto, the transparent electrode may comprise a main conductive part 11 having a plurality of grid structures including line patterns 111 made of liquid metal, a protective part 13 surrounding the upper and side portions of the plurality of grid structures, and an auxiliary conductive part 15 located adjacent to the lower portions of the grid structures of the main conductive part.

The main conductive part 11 is demonstrated in that line patterns 111 are formed into a plurality of grid structures to improve the charge uniformity of the electrode, thereby increasing power conversion efficiency (PCE).

The liquid metal may include a metal having high metal conductivity and excellent elasticity in order to improve charge uniformity, for example, at least one metal selected from the group consisting of eutectic gallium-indium alloy (EGaIn) and GaInSn (Galinstan), and preferably includes a eutectic gallium-indium alloy, having viscosity suitable for a printing process.

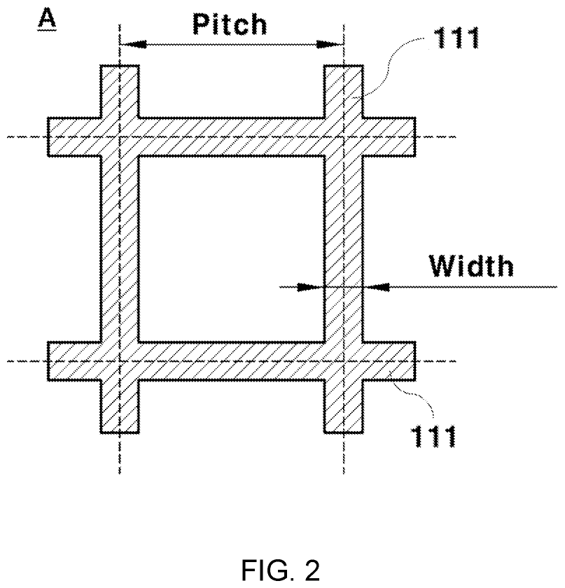

FIG. 2 is an enlarged plan view of the grid structure A of the main conductive part in the transparent electrode for a solar cell according to an exemplary embodiment. With reference thereto, the line patterns 111 at specific width may form a plurality of grid structures A having specific pitch. The pitch refers to a distance between adjacent line patterns 111 extending in the same direction.

Specifically, the width of the line patterns 111 may be 20 μm or less or 1 to 20 μm, and preferably 1 μm to 10 μm. Outside of the above range, if the width of the line patterns 111 is too narrow, sheet resistance may increase, whereas if the width of the line patterns 111 is too wide, transmittance may decrease.

Also, the pitch of the grid structures may be 500 μm or less, and preferably 100 μm to 200 μm. Outside of the above range, if the pitch of the grid structures is too narrow, transmittance may decrease, whereas if the pitch of the grid structures is too wide, sheet resistance may increase.

Also, since the liquid metal is provided in the form of grid structures, the outermost portion of each of the grid structures may further include a thin oxide layer due to surface oxidation. The oxide layer not only serves to improve elasticity along with the protective part, but also confers self-healing properties due to maintenance of the grid structure.

Since the transparent electrode for a solar cell comprises the main conductive part including the grid structures having specific pitch and the line patterns 111 having specific width, the frequency of carriers capable of reaching the electrode increases. Therefore, the charge carrier recombination is reduced, and thus high power conversion efficiency (PCE) is increased.

The protective part 13 may be capable of embedding liquid metal in the form of grid structures by surrounding the upper and side portions of the grid structures of the main conductive part 11, other than the lower portions thereof, and also of maintaining elasticity by including an elastomer.

The elastomer may include a transparent elastomer in order to maintain elasticity and increase transmittance, and preferably includes a thermosetting elastomer resin, for example, at least one selected from the group consisting of polydimethylsiloxane (PDMS) and thermoplastic polyurethane elastomer (TPE). More preferably, PDMS, which is transparent in the range of visible and infrared, is used.

The protective part 13 may protect the main conductive part 11 from external force and chemical exposure while maintaining elasticity, and also includes a transparent elastomer to increase light transmittance to thus impart bifacial properties.

The auxiliary conductive part 15 may be located adjacent to the lower portions of the grid structures of the main conductive part 11, and serves to come into contact with the liquid metal in the main conductive part 11 to thus form an electrical path. The auxiliary conductive part 15 may be of a sheet shape.

To this end, the auxiliary conductive part 15 may include a conductive material, and preferably includes a transparent conductive material that is used as a conventional transparent electrode in order to increase transparency, for example, at least one selected from the group consisting of indium tin oxide (ITO), fluorine doped tin oxide (FTO), carbon nanomaterial, and conductive polymer. More preferably, ITO, which is transparent in the visible and infrared ranges and the thickness of which is easy to be controlled for being a conductive material.

In particular, the transparent electrode for a solar cell according to an exemplary embodiment may be used as a top electrode, among electrodes of a perovskite solar cell.

Accordingly, the power conversion efficiency (PCE) of the transparent electrode for a solar cell according to an exemplary embodiment satisfying the above characteristics is 10% to 14%, which corresponds to 90% or more of the power conversion efficiency of the opaque electrode used as the conventional top electrode, and is thus almost the same as the conventional efficiency.

Also, the average visible-light transmittance (AVT) of the transparent electrode for a solar cell according to an exemplary embodiment is 78% to 82%, which is almost the same as the transmittance of a conventional top electrode.

Specifically, the transparent electrode for a solar cell according to an exemplary embodiment may include the main conductive part 11, having the plurality of grid structures, and further includes the auxiliary conductive part 15 under the same, so even when used as a top electrode, power conversion efficiency (PCE) is excellent, and there is a significant advantage in that average visible-light transmittance is sufficient to implement bifacial properties.

In addition, a method of manufacturing the transparent electrode for a solar cell according to another embodiment may include applying a sacrificial layer on a substrate (S10), forming a main conductive part 11 by forming a plurality of grid structures on the sacrificial layer through a printing process using liquid metal (S20), forming a protective part 13 so as to surround the upper and side portions of the plurality of grid structures by placing an elastomer on the main conductive part 11 (S30), separating the substrate from the main conductive part 11 and the protective part 13 by removing the sacrificial layer (S40), and locating an auxiliary conductive part 15 including a conductive material so as to be provided adjacent to the lower portions of the grid structures of the main conductive part 11 (S50). The method of manufacturing the transparent electrode for a solar cell may include content substantially overlapping that of the transparent electrode for a solar cell described above, and a description redundant therewith is omitted.

In the step of applying the sacrificial layer (S10), the sacrificial layer is applied on the substrate such that the substrate serves as a support for forming the main conductive part 11, and only the main conductive part 11 and the protective part 13 are left behind later.

The substrate is not particularly limited, so long as it is able to serve as a support layer capable of forming a main conductive part 11 in the form of grid structures on the sacrificial layer, and may be, for example, a substrate selected from the group consisting of a silicon wafer and a silicon oxide wafer.

The sacrificial layer is not particularly limited, so long as it is a layer that may be separated by a solution used to separate the substrate from the main conductive part 11 and the protective part 13 later, and may include, for example, at least one selected from the group consisting of LOR (lift-off resist) 3A and PMMA (poly(methyl methacrylate)).

The applying the sacrificial layer on the substrate may be performed using a typical coating process useful in the field of solar cells, for example, spin coating, blade coating, or bar coating.

The forming the main conductive part (S20) is a step of forming a main conductive part 11 by forming a plurality of grid structures on the sacrificial layer through a printing process using liquid metal.

In the printing process, the liquid metal is linearly printed on the sacrificial layer, the substrate is rotated in a plane, and then the liquid metal is linearly printed at 90° in the plane with the previously linearly printed liquid metal to form grid structures, whereby the liquid metal is ultimately manufactured into a plurality of grid structures including the line patterns 111.

Specifically, in the printing process, the liquid metal may be ejected onto the sacrificial layer on the substrate from a nozzle containing the liquid metal therein through pneumatic pressure. Then, the nozzle may be moved linearly to print the liquid metal linearly. Then, the substrate is rotated in a plane, after which the liquid metal is printed linearly in the same manner at 90° in the plane with the previously linearly printed liquid metal to form grid structures, whereby the liquid metal may be ultimately manufactured into a plurality of grid structures including the line patterns 111.

Here, the width of the line patterns 111 and the pitch of the grid structures may be adjusted through corresponding line width adjustment during each line-printing step of the printing process.

Since the method of manufacturing the transparent electrode for a solar cell according to another embodiment is capable of forming the main conductive part having a plurality of grid structures through a printing process using liquid metal, an additional process for depositing a buffer layer or the like is not required, and the electrode-manufacturing time is shortened. Moreover, it is easy to optimally adjust the width of the line patterns 111 and the pitch of the grid structures.

The forming the protective part (S30) is a step of placing an elastomer on the main conductive part 11 so as to surround the upper and side portions of the plurality of grid structures.

Here, the elastomer is not provided under the plurality of grid structures, so only the auxiliary conductive part 15 and the lower portions of the plurality of grid structures may contact the liquid metal.

The placing the elastomer so as to surround the upper and side portions of the plurality of grid structures in the main conductive part 11 may be performed using a typical process useful in the field of solar cells, for example spin coating or bar coating.

The separating the substrate (S40) is a step of separating the substrate from the main conductive part 11 and the protective part 13 by removing the sacrificial layer.

In the separation process, a solution for removing the sacrificial layer may be provided, thereby separating the substrate from the main conductive part 11 and the protective part 13.

The solution for removing the sacrificial layer may include at least one selected from the group consisting of Mr-rem 700 and acetone, and is not limited to a specific solution.

The locating the auxiliary conductive part 15 (S50) is a step of locating the auxiliary conductive part 15 including a conductive material so as to be provided adjacent to the lower portions of the grid structures of the main conductive part 11.

Here, the auxiliary conductive part 15 including the conductive material may be located alone, but by locating the initial solar cell stack along with the auxiliary conductive part 15, one surface of the auxiliary conductive part 15 may be located adjacent to the lower portions of the grid structures of the main conductive part 11.

The initial solar cell stack may be a stack excluding the top electrode of the perovskite solar cell, and preferably, the initial stack includes a hole transport layer (HTL) on the remaining surface of the auxiliary conductive part 15, a perovskite layer on the hole transport layer, an electron transport layer (ETL) on the perovskite layer, a bottom electrode on the electron transport layer, and a glass layer on the bottom electrode, which are disposed in that sequence.

The method of manufacturing the transparent electrode for a solar cell according to another embodiment is advantageous in view of mass production and large-area application because the electrode-manufacturing process may be performed separately from other solar-cell-manufacturing processes such as an initial solar cell stack assembly process.

A better understanding of the present invention may be obtained through the following examples. These examples are merely set forth to illustrate the present invention, and are not to be construed as limiting the present invention.

### Example 1: Manufacture of Solar Cell Including Transparent Electrode for Solar Cell as Top Electrode

(S10) A silicon wafer was prepared as a substrate, and a sacrificial layer including a LOR (lift-off resist) 3A was applied on the substrate through spin coating.

(S20) A main conductive part including a plurality of grid structures was manufactured through a printing process using a nozzle containing a eutectic gallium-indium alloy (EGaIn) as a liquid metal therein. Here, the width of the line patterns was 5 μm and the pitch of the grid structures was 100 μm.

(S30) A protective part was formed by subjecting an elastomer, particularly PDMS, which is a transparent curable elastomer, to spin coating so as to surround the upper and side portions of the plurality of grid structures.

(S40) The substrate was separated from the main conductive part and the protective part using mr-Rem 700 as a solution for removing the sacrificial layer.

(S50) An auxiliary conductive part including ITO, which is a conductive material, was located so as to be adjacent to the lower portions of the grid structures of the main conductive part. Specifically, the main conductive part and the transparent part were located on one surface of the auxiliary conductive part included in the initial solar cell stack.

Here, the initial solar cell stack included a hole transport layer (HTL) on the remaining surface of the auxiliary conductive part, a perovskite layer on the hole transport layer, an electron transport layer (ETL) on the perovskite layer, a bottom electrode on the electron transport layer, and a glass layer on the bottom electrode, which were sequentially disposed.

Accordingly, a solar cell, including, as a top electrode, a transparent electrode for a solar cell including the main conductive part, the protective part, and the auxiliary conductive part, was ultimately manufactured.

### Example 2: Manufacture of Solar Cell Including Transparent Electrode for Solar Cell Having Different Grid Structure Sizes as Top Electrode

A solar cell was manufactured in the same manner as in Example 1, with the exception that the main conductive part was manufactured so as to have a plurality of grid structures, in which the width of the line patterns was 10 μm and the pitch of the grid structures was 200 μm, unlike Example 1.

### Example 3: Manufacture of Solar Cell Including Transparent Electrode for Solar Cell Having Different Grid Structure Sizes as Top Electrode

A solar cell was manufactured in the same manner as in Example 1, with the exception that the main conductive part was manufactured so as to have a plurality of grid structures, in which the width of the line patterns was 20 μm and the pitch of the grid structures was 500 μm, unlike Example 1.

### Comparative Examples 1 to 4: Manufacture of Transparent Electrodes for Solar Cells Including Different Types of Top Electrodes

Respective solar cells were manufactured in the same manner as in Example 1, with the exception that the top electrode was manufactured using indium tin oxide (ITO) (Comparative Example 1), thin gold (Au) (10 nm) (Comparative Example 2), thin silver (Ag) (10 nm) (Comparative Example 3), and poly(3,4-ethylenedioxythiophene)polystyrene sulfonate (PEDOT:PSS) (Comparative Example 4), rather than using the transparent electrode for a solar cell according to an exemplary embodiment as the top electrode, as in Example 1.

### Test Example 1: Evaluation of Power Conversion Efficiency (PCE) and Average Visible-Light Transmittance (AVT) of Transparent Electrode for Solar Cell

The solar cell including the transparent electrode of each of Examples 1 to 3 and Comparative Examples 1 to 4 as a top electrode was manufactured, and the power conversion efficiency (PCE) and average visible-light transmittance (AVT) thereof were measured. The results thereof are shown in Table 1 below.

Specifically, PCE was determined by irradiating the manufactured solar cell with light at 100 mW/cm² (1, Sun) using an ORIEL sol 3A, applying a voltage from −0.1 V to 1.2 V, measuring values such as V_{oc}, J_{sc} and fill factor (FF), and substituting the values into the following equation.

$$PCE = ( {V}_{oc} \times {J}_{sc} \times FF ) / ( {P}_{i n} )$$

Here, Pᵢₙ represents 1 Sun (100 mW/cm²).

AVT was measured using a UV/VIS spectrophotometer.

TABLE 1

| | | | | | Fill | | Efficiency | |
|---|---|---|---|---|---|---|---|---|
| | Width | Pitch | V_{oc} | J_{sc} | Factor | PCE | relative to Au | AVT |
| Note | (μm) | (μm) | (V) | (mA/cm²) | (%) | (%) | (%) | (%) |
| Ref Gold (Au) | — | — | 1.06 | 22.18 | 59.89 | 14.08 | Ref | 0 |
| Comparative Example 1 | — | — | 0.96 | 5.73 | 23.47 | 1.30 | 9.2 | 85 |
| Comparative Example 2 | — | — | 0.051 | 0.010 | 25.0 | 0.001 | 0.007 | 40 |
| Comparative Example 3 | — | — | 0.015 | 0.051 | 23.1 | 0.0001 | 0.0007 | 45 |
| Comparative Example 4 | — | — | 0.88 | 0.84 | 20.4 | 2.32 | 16.4 | 90 |
| Example1 | 5 | 100 | 1.09 | 21.04 | 59.05 | 13.54 | 96.1 | 80 |
| Example2 | 10 | 200 | 1.10 | 21.73 | 54.61 | 13.03 | 92.5 | 80 |
| Example3 | 20 | 500 | 1.08 | 21.84 | 46.76 | 11.02 | 78.2 | 80 |

As is apparent from Table 1, the solar cells according to Examples 1 to 3 had very high power conversion efficiency (PCE) compared to the solar cells according to Comparative Examples 1 to 4. In particular, even when the width and pitch between the grid structures were large, as in the solar cell according to Example 3, the current density (J_{sc}) was maintained constant compared to the solar cells according to Comparative Examples 1 to 4, manufactured using different types of transparent electrodes, so the power conversion efficiency (PCE) was relatively high. In particular, the solar cells according to Examples 1 to 3 exhibited similar power conversion efficiency (PCE) compared to when gold (Au) was used as an opaque electrode, and moreover, the average visible-light transmittance (AVT) thereof was equivalent to those of the solar cells according to Comparative Examples 1 to 4, manufactured using different types of transparent electrodes.

Therefore, it can be confirmed that the transparent electrode for a solar cell according to an exemplary embodiment has visible-light transmittance equivalent to that of a conventional transparent electrode, and also power conversion efficiency (PCE) equivalent to that of a conventional opaque electrode.

Moreover, it can be confirmed that the power conversion efficiency (PCE) of the solar cells according to Examples 1 to 3 increased with a decrease in the width and pitch between the grid structures. Specifically, the denser the grid structures of the main conductive part, the higher the power conversion efficiency (PCE), and as the grid structures become denser, the frequency of carriers that can reach the electrode becomes much higher, which reduces charge carrier recombination and thus increases the power conversion efficiency (PCE).

### Test Example 2: Evaluation of Optical Properties Such as Bifacial Properties of Transparent Electrode for Solar Cell

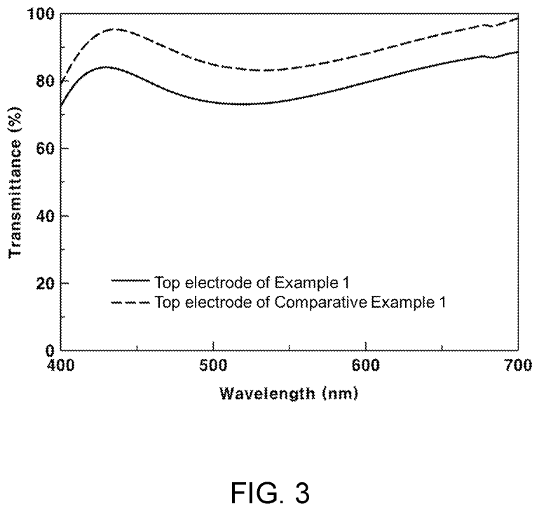

The transmittance and sheet resistance of only the top electrode in the solar cell manufactured according to Example 1 and the transmittance and sheet resistance of only the top electrode (ITO) in the solar cell manufactured according to Comparative Example 1 were measured, and the results thereof are shown in FIG. 3 and in Table 2 below.

Specifically, FIG. 3 is a graph showing the transmittance (%) of the top electrode (ITO) of Comparative Example 1 and the top electrode of Example 1 depending on the wavelength (nm).

TABLE 2

| | | Sheet |
|---|---|---|
| | Transmittance | resistance |
| Classification | (%) | (Ω/sq) |
| Top electrode (ITO) of | 89.4 | 34.4 (±0.27) |
| Comparative Example 1 | | |
| Top electrode of Example 1 | 79.6 | 0.44 (±0.03) |

As is apparent from FIG. 3 and Table 2, the transmittance of the top electrode of Example 1 was decreased by about 10% compared to that of the conventional transparent electrode (ITO), but the sheet resistance thereof was lowered by 300% or more. It can be confirmed that the transparent electrode for a solar cell according to an exemplary embodiment can significantly increase the power conversion efficiency (PCE) by greatly lowering the sheet resistance while maintaining the transmittance compared to the conventional transparent electrode. Meanwhile, in order to evaluate the bifacial properties of the solar cell manufactured according to Example 3, the power conversion efficiency (PCE) was measured after radiating light onto the glass part at the bottom electrode side or onto the transparent electrode for a solar cell at the top electrode side. The results thereof are shown in Table 3 below.

TABLE 3

| Illumination | Voc | Isc | Fill Factor | PCE |
|---|---|---|---|---|
| Direction | (V) | (mA) | (%) | (%) |
| Glass part (bottom | 1.00 | 1.86 | 49.76 | 10.20 |
| electrode side) | (±0.010) | (±0.015) | (±1.977) | (±0.590) |
| Transparent electrode | 0.98 | 1.74 | 49.40 | 9.32 |
| for solar cell (top | (±0.005) | (±0.001) | (±1.675) | (±0.362) |
| electrode side) | | | | |

As is apparent from Table 3, compared to the efficiency (10.20%) when radiating light toward the glass, the efficiency (9.32%) when radiating light toward the electrode was 91.3%, based on which it was confirmed that the transparent electrode for a solar cell according to an exemplary embodiment had bifacial properties. The transparent electrode for a solar cell according to an exemplary embodiment includes the main conductive part having a plurality of grid structures made of liquid metal and formed at a specific pitch and width, and further includes the auxiliary conductive part under the same, so even when used as a top electrode, power conversion efficiency (PCE) is excellent, and there is a significant advantage in that average visible-light transmittance is sufficient to implement bifacial properties.

The invention has been described in detail with reference to preferred embodiments thereof. However, it will be appreciated by those skilled in the art that changes may be made in these embodiments without departing from the principles or spirit of the invention, the scope of which is defined in the appended claims and their equivalents.

1.-10. (canceled)

11. A method of manufacturing a transparent electrode for a solar cell, the method comprising:
applying a sacrificial layer on a substrate;
forming a plurality of grid structures on the sacrificial layer using a liquid metal to provide a main conductive part;
forming a protective part so as to surround the plurality of grid structures;
separating the substrate from the main conductive part and the protective part by removing the sacrificial layer; and
locating an auxiliary conductive part comprising a conductive material so as to be provided under the grid structures of the main conductive part.

12. The method of claim 11, wherein the sacrificial layer comprises at least one selected from the group consisting of LOR (lift-off resist) 3A, PMMA (poly(methyl methacrylate)) and combinations thereof.

13. The method of claim 11, wherein the liquid metal comprises a eutectic gallium-indium alloy (EGaIn).

14. The method of claim 11 wherein the protective part comprises an elastomer.

15. The method of claim 14, wherein the elastomer comprises at least one selected from the group consisting of polydimethylsiloxane (PDMS), thermoplastic polyurethane elastomer (TPE) and combinations thereof.

16. The method of claim 11, wherein the conductive material comprises at least one selected from the group consisting of indium tin oxide (ITO), transparent conductive oxide (TCO), carbon nanomaterial, conductive polymer and combinations thereof.

17. The method of claim 11, wherein the conductive material is ITO, which is transparent in the range of visible and infrared.

18.-20. (canceled)
